(19) United States
(12) Patent Application Publication
(10) Pub. No.: US 2012/0289397 A1
(43) Pub. Date: Nov. 15, 2012

(54) METHOD OF FABRICATION OF NANO PARTICLE COMPLEX CATALYST BY PLASMA ION IMPLANTATION AND DEVICE FOR THE SAME

(75) Inventors: Ji Young BYUN, Seoul (KR); Seung Hee HAN, Seoul (KR); Heon Phil HA, Seoul (KR); Byung Yong YU, Seoul (KR); Sang Hoon KIM, Gyeonggi-Do (KR); Do Hyung KIM, Seoul (KR); Chae Sun LIM, Incheon (KR)

(73) Assignee: KOREA INSTITUTE OF SCIENCE AND TECHNOLOGY, Seoul (KR)

(21) Appl. No.: 13/288,129

(22) Filed: Nov. 3, 2011

(30) Foreign Application Priority Data
May 11, 2011 (KR) 10-2011-0044051

(51) Int. Cl. B01J 37/34; H01J 37/317; B82B 3/00

(52) U.S. Cl. 502/5; 250/492.3; 977/840

(57) ABSTRACT

Provided is a method of fabricating a nano particle complex catalyst including generating a plasma ion of a solid element and performing plasma ion implantation to carry a catalyst component of the solid element in a porous carrier. In the method, a pulse direct current voltage is applied to the deposition source to generate the plasma ion of the solid element, and a synchronized voltage is applied to the porous carrier, thereby instantly applying a pulse high voltage to the solid element. The ionized solid element is accelerated toward the porous carrier by the pulse high voltage instantly applied to the solid element, thereby performing the ion implantation.

### CROSS-REFERENCE TO RELATED APPLICATION

This application claims priority to and the benefit of Korean Patent Application No. 2011-0044051, filed May 11, 2011, the disclosure of which is incorporated herein by reference in its entirety.

### BACKGROUND

1. Field of the Invention

The present invention relates to a method of fabricating a nano particle complex catalyst including a nano-scale catalyst particle by carrying a catalyst component of a solid element in a porous carrier, which includes generating a plasma ion of a solid element, accelerating the plasma ion and implanting the plasma ion into the porous carrier, and a device used in the method.

2. Discussion of Related Art

A method generally used to fabricate a catalyst by supporting a catalyst active component particle in a porous carrier (hereinafter, also referred to as a “catalyst component” or “catalyst particle”) includes a method of dipping a porous carrier in a solution in which a catalyst element is dissolved to penetrate the solution into the porous structure or dipping a porous carrier in a slurry in which a catalyst component is dispersed to penetrate a catalyst particle into the porous structure. It is generally called “impregnation.”

That is, a solution containing a catalyst particle or catalyst component is penetrated into a porous structure of a porous carrier by impregnating the porous carrier in an environment in which the catalyst component is dissolved or dispersed for a predetermined time, and is then heated to remove a solvent component, thereby fabricating a catalyst in a state that the catalyst component is carried in every part of the porous structure. According to this method, a porous structure in which fine catalyst particles are dispersed may be fabricated.

When a catalyst is fabricated by such impregnation, the catalyst to be supported may have a small particle size of several nanometers, but it may also have a large particle size of several tens of nanometers. Due to the increase in average particle size, a catalyst characteristic may be degraded.

In addition, to carry a predetermined amount of catalyst components in a carrier, a larger amount of catalyst particles than that of the catalyst components needs to be fabricated in a slurry or solution phase, and generally a material used as a catalyst component is an expensive noble metal. Therefore, when a catalyst is fabricated by the impregnation, an expensive catalyst component may be wasted. For example, a micro reactor uses a catalyst activating plate having a carrier on only one surface of a metal plate. Here, a catalyst component should be carried only in a carrier to fabricate the catalyst activating plate, but the impregnation has a problem in that the catalyst components also remain on a surface of a metal plate having no carrier, which is not cost-effective in the fabrication of the catalyst.

Meanwhile, as a method of reforming a material surface, ion implantation is used. The ion implantation is a technique of accelerating ions with a high energy of several to several hundreds of keV to input the ions to a surface of a metal material. According to such ion implantation, a layer which is reformed to a thickness of several thousands of Å may be formed from a material surface, and a smooth composition changing layer may be formed, thereby basically preventing peeling due to the difference in characteristics between materials as in coatings. Since the ion implantation is a high energy process, there is almost no thermodynamic limit. Since the ion implantation is also performed at room temperature, there is neither size change according to an increase in temperature of a sample nor degradation according to heat.

In addition, the ion implantation is rarely affected by surface roughness, and easily modulates a kind, thickness and a degree of reforming of a reformed layer by modulating a kind, energy and an amount of implanted ions.

However, since the ion implantation was developed to dope impurities into a planar sample, a semiconductor wafer, there is a systemic limit to its use for other purposes. That is, to uniformly implant ions when the ions extracted from an ion source are accelerated and input to a sample in a type of an ion beam, the ion beam should be shaken. In addition, due to a fundamental limitation of line-of-sight implantation, the method of implanting ions in an ion beam type has technical disadvantages of three-direction rotation of a sample for ion implantation into a three-dimensional material such as a mold, a tool or a machine part and the necessity of masking to prevent sputtering caused by an oblique incident ion.

To overcome such disadvantages regarding the ion implantation of the ion beam type, plasma ion implantation using plasma and a high voltage pulse (disclosed in U.S. Pat. No. 4,764,394, Korean Patent No. 137704, European Patent No. 480688, Canadian Patent No. 2052080 and U.S. Pat. No. 5,126,163) has been suggested. This technique enables uniform and fast ion implantation into a large-scale three-dimensional sample, and does not need an ion beam dispersing device.

However, most of the currently suggested plasma ion implantation techniques can only implant gaseous ions such as nitrogen, oxygen, argon or methane, but not to implant plasma ions of an element that is present in a solid phase. While some prior arts (U.S. Pat. Nos. 5,777,438 and 5,126,163) disclose solid plasma ion implantation using a pulse negative arch, when the pulse negative arc plasma is used, a large-sized macro particle (droplet) is generated due to the arc and deposited on a surface of an ion implanted sample. To prevent this phenomenon, a filter using a magnetic field needs to be used.

### SUMMARY OF THE INVENTION

The present invention is directed to providing a method of implanting a plasma ion of a solid element to carry a catalyst component of the solid element in a porous carrier. To this end, the present invention provides a method of effectively containing the catalyst component of the solid element in a porous carrier. That is, a method of fabricating a catalyst composed of solid elements to achieve desirable performance of catalytic activity even when using a smaller amount of catalyst components than that in a conventional impregnation.

The present invention is also directed to providing a device for fabricating a nano particle complex catalyst, which can use the above-mentioned method.

One aspect of the present invention provides a method of fabricating a nano particle complex catalyst, which includes generating a plasma ion of a solid element used as a catalyst component in a vacuum container maintained in a vacuum state and accelerating and implanting an ionized catalyst component from the generated plasma ion into a surface of a porous carrier.

The solid element plasma ion may be generated by supplying pulse direct current power which is maintained at low average power but has a high power level at the moment a pulse is applied to a deposition source.

The pulse direct current power may have a density of 10 W/cm² to 10 kW/cm², a frequency of 1 Hz to 10 kHz and a pulse width of 10 μsec to 1 msec.

A high voltage pulse synchronized with the pulse direct current power may be applied to the porous carrier to accelerate a solid element plasma ion toward the porous carrier.

The high voltage pulse may have a frequency of 1 Hz to 10 kHz, a pulse width of 1 μsec to 200 μsec and a negative-pulse high voltage of −1 to −100 kV.

A plasma generating gas may be injected to the vacuum container at a pressure of 0.5 to 5 mTorr.

The porous carrier may be at least one selected from the group consisting of Si—O, Sn—O, Al—O, Cr—O, Mo—O, Ti—O, Zr—O, Mg—O, W—O, V—O, Sb—O, and RE (rare earth elements: Sr, Y, lanthanum group)-O-based oxides.

The solid element may be one selected from the group consisting of Au, Ag, Cu, Co, Ni, Pt, Pd, Ru, Ir and Rh.

Plasma may be further introduced into the vacuum container.

The porous carrier may include a carrier layer having a thickness of 1 to 100 μm, which is formed on a metal or ceramic substrate.

Another aspect of the present invention provides a device for fabricating a nano particle complex catalyst, which includes a vacuum container maintained in a vacuum state, a deposition source for emitting an ion of a solid element into the vacuum container by pulse direct current power which is maintained at a low average power but has a high power level at the moment a pulse is applied, and a porous carrier disposed in the vacuum container to face the deposition source and implanting the ion of the solid element by a high voltage pulse synchronized with the pulse direct current power.

A plasma generating gas may be implanted into the vacuum container to form an ion of a solid element in a plasma state.

Plasma may be further introduced into the vacuum container.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a diagram illustrating components of a device for implanting a solid element plasma ion into a porous carrier according to one embodiment of the present invention;

FIG. 2 is a transmission electron microscope (TEM) image illustrating a surface of a catalyst fabricated according to an example;

FIG. 3 is a TEM image illustrating a surface of a catalyst fabricated according to a comparative example; and

FIG. 4 is a diagram illustrating a hydrogen yield according to a temperature in a hydrogen gas generating reaction through dimethylether (DME) reforming.

### DETAILED DESCRIPTION OF EXEMPLARY EMBODIMENTS

The present invention relates to a method of fabricating a catalyst in which a solid element used as a catalyst component is carried on a surface of a porous carrier, thereby carrying a nano particle of the catalyst component in the porous carrier. This method is performed to uniformly disperse an active catalyst in a size of a nano particle using plasma ion implantation instead of conventional impregnation. When the impregnation is used, a size of a catalyst particle is several to several tens of nanometers, and thus the present invention uses the ion implantation to uniformly disperse a catalyst particle in a size of several nanometers.

In addition, the impregnation essentially includes a process of dipping a catalyst carrier in a liquid and thus needs a subsequent process of removing the liquid by evaporation. Here, a noble metal catalyst is coated on an unnecessary part of the catalyst carrier, resulting in an increase in amount of the noble metal used. However, since the ion implantation is a dry process, such an evaporation removing process is not needed and a catalyst component may be carried only in a carrier of interest.

Specifically, the present invention provides a method of fabricating a nano particle complex catalyst by generating a plasma ion of a solid element used as a catalyst component in a vacuum container maintained in a vacuum state and accelerating and implanting the ionized catalyst component into a surface of a porous carrier from the generated plasma ion.

To generate a plasma ion of a solid element in a vacuum carrier, a deposition source capable of sputtering a solid element such as magnetron is used. Power should be supplied to the deposition source to sputter the solid element. Here, the power supplied to the deposition source is a pulse-type direct current power which is maintained at low average power but has a high power level at the moment a pulse is applied.

When the pulse direct current power is supplied to the deposition source, the deposition source is in a pulse-on state, and from the deposition source, the solid element is sputtered into the vacuum container. Then, the solid element ions are in a plasma state due to a high-density plasma generating gas present in the vacuum container. To implant the solid element ions in the plasma state to a porous carrier, the porous carrier is disposed toward the deposition source, and a high voltage pulse is applied thereto. That is, effective ion implantation may be performed by accelerating the solid element ions in the plasma state toward the porous carrier due to the high voltage pulse applied to the porous carrier.

To sputter the solid element used as the catalyst component, a pulse direct current power supplied to the deposition source has a density of 10 W/cm² to 10 kW/cm², a frequency of 1 Hz to 10 kHz and a pulse width of 10 μsec to 1 msec. The high voltage pulse applied to accelerate the solid element ion toward the porous carrier is synchronized to have the same frequency of 1 Hz to 10 kHz as the pulse direct current power supplied to the deposition source before use, and has a pulse width of 1 to 200 μsec and a negative-pulse high voltage of −1 to −100 kV.

In the present invention, the solid element used as the catalyst component may be at least one selected from the group consisting of Au, Ag, Cu, Co, Ni, Pt, Pd, Ru, Ir and Rh. The deposition source is operated in a pulse mode rather than a continuous mode, targeting the solid element. This increases an ionization rate of the solid element emitted from the surface of the deposition source by generating high-density solid element ions on the surface of the deposition source. The high-density solid element ions may be generated when low average power is maintained in order to avoid problems with cooling of the deposition source, but very high power is supplied at the moment a pulse is applied.

When a large amount of the solid element ions generated in the above-mentioned method are emitted into the vacuum container, they are in a plasma state due to a plasma generating gas present in the vacuum container. Here, the plasma generating gas filled in the vacuum container used herein may be argon, nitrogen, oxygen, methane, carbon monoxide, carbon dioxide, ammonia, acetylene, benzene gas and a mixture thereof. A pressure of this gas is modulated within 0.5 to 5 mTorr. When the pressure in the vacuum container is less than 0.5 mTorr, it is difficult to generate plasma, and when the pressure therein is more than 5 mTorr, energy loss of the solid element ion is severely increased due to frequent collision between the solid element ion and gas particles.

A negative-charged high voltage pulse is applied to the porous carrier to effectively implant the solid element ions generated in the plasma state into the porous carrier disposed to face the deposition source. When the negative high voltage pulse is applied to the porous carrier, ions are extracted from the solid element plasma generated from the deposition source and accelerated toward the porous carrier, thereby achieving effective ion implantation.

The high voltage pulse should be synchronized with the pulse direct current voltage applied to the deposition source. This is because the solid element sputtered from the deposition source at the moment the deposition source is in a pulse-on state by the pulse direct current voltage applied to the porous carrier should be ionized in the vacuum container, and accelerated toward the porous carrier by the high voltage pulse applied to the porous source to compete the ion implantation. The high voltage pulse may have a voltage of −1 to −100 kV.

In the present invention, the porous carrier may be selected from the group consisting of Si—O, Sn—O, Al—O, Cr—O, Mo—O, Ti—O, Zr—O, Mg—O, W—O, V—O, Sb—O, and RE (rare earth elements: Sr, Y, lanthanum group)-O-based oxides.

In use, the porous carrier may be placed on an installation plate formed of a conductive material to which a high voltage pulse may be applied. The installation plate may be formed of any conductive material such as copper or stainless steel without limitation.

Subsequently, the porous carrier may be coated on a metal substrate or ceramic substrate, and have a coating thickness of 1 to 100 μm.

In addition to the plasma generating gas, plasma may be further introduced into the vacuum container from an external environment. The plasma introduced into the vacuum container from the external environment may not only increase an ionization rate of the solid element emitted from the deposition source, but also enable the deposition source to operate at a lower pressure than the operation pressure, thereby minimizing the collisions with the gas particles in the ion implantation.

To introduce the plasma, an inductively coupled plasma of a plasma generating gas previously present in the vacuum container may be generated by applying RF power to an RF antenna, or filament discharging or microwaves may be used.

In the present invention, a size of the solid element right after the implantation into the porous carrier is several nanometers. Thus, the catalyst fabricated in the present invention is a nano particle complex catalyst in which a catalyst component is present in a nano level. Compared to catalyst component particles fabricated by the impregnation having a size of several to several tens of nanometers, the nano particle complex catalyst in the present invention has a smaller size, which has an effect of increasing a surface area of a catalyst active component in the catalyst fabricated in the present invention.

Further, ions of the solid element implanted into the carrier according to the method of the present invention are more strongly interacted with the surface of the porous carrier, compared to those in the impregnation. Thus, although the solid element is exposed to a catalyst-used environment including a high temperature and high pressure, it is expected to be less sintered, and thus performance of the catalyst is not easily degraded even in long-term use.

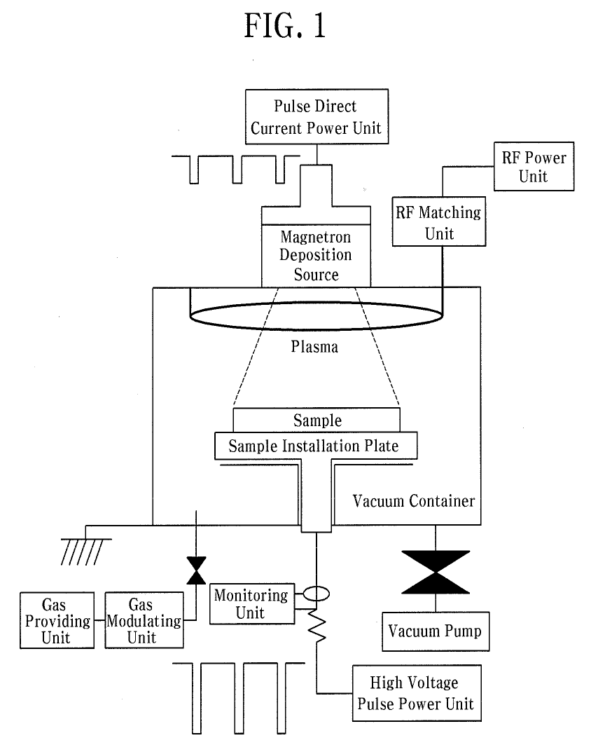

Meanwhile, as an exemplary embodiment of a device capable of performing the method of fabricating a catalyst in the present invention, a device described in the pending Korean application entitled “Solid Element Plasma Ion Implantation Device” (Korean Patent Application No. 10-2009-0002986) shown in FIG. 1 may be used. That is, a solid element which is a catalyst component targeting magnetron may be loaded to operate in a pulse mode using pulse direct current power, and a high voltage pulse synchronized with the solid element may be applied to a porous carrier used as a sample, thereby performing ion-implantation into a surface of the porous carrier by accelerating ions of the solid element generated from the magnetron. However, the device capable of performing the method according to the present invention is not limited to a device disclosed in the above-mentioned invention. Any device including a vacuum container maintained in a vacuum state, a deposition source emitting an ion of a solid element into the vacuum container by pulse direct current power which is maintained at a low average power but has a high power level at the moment a pulse is applied, and a porous carrier disposed in the vacuum container to face the deposition source and implanting the ion of the solid element by a high voltage pulse synchronized with the pulse direct current power may be used without limitation.

Further, to form a solid element in a plasma state, argon, nitrogen, oxygen, methane, carbon monoxide, carbon dioxide, ammonia, acetylene, and benzene gases and a mixture thereof may be injected into the vacuum container of the device at a pressure of 0.5 to 5 mTorr. To increase an ionization rate of the solid element and effectively perform ion implantation of the solid element to the porous carrier, an inductively coupled plasma of a plasma generating gas previously present in the vacuum container may be generated by an RF antenna, or an external plasma may be further introduced using filament discharging or using microwaves.

In addition, an ion is implanted by applying a high voltage pulse when the porous carrier is placed on an installation plate formed of a conductive material to apply the high voltage pulse to the porous carrier.

Hereinafter, the present invention will be described in detail with reference to Examples. However, the Examples are provided to help understanding of the present invention, and the present invention is not limited thereto.

### EXAMPLE

A solid element, platinum (Pt), was used as a target for a magnetron deposition source. The Pt target used herein had a diameter of 75 mm and a thickness of 1 mm. As a porous carrier for ion implantation, porous γ-alumina (thickness: 26 μmm) fabricated through anodizing was used. A porous γ-alumina layer was formed on one side of an Al plate having a length of 4 cm and a width of 2 cm by anodic oxidation.

The porous alumina carrier layer was loaded on a conductive sample plate, and air was exhausted from the vacuum container at a vacuum rate of 5×10⁻⁶ Torr, and then argon gas was input to maintain an argon pressure in the vacuum container of 2 mTorr. Subsequently, RF power of 13.56 MHz and 200 Watt was applied to an antenna for generating plasma to generate argon plasma, and pulse direct current power was supplied to the magnetron deposition source to operate the magnetron deposition source. The pulse direct current voltage applied was −1.1 kV, a pulse current was 10 Å, and a pulse power was approximately 200 W/cm². In addition, a frequency of the pulse direct current power was 100 Hz, and a pulse width was 200 μsec. An average power was 220 W to avoid the problem of cooling the magnetron deposition source.

A plasma ion implantation process was performed for 30 minutes by operating the magnetron deposition source using the above-mentioned method and simultaneously applying a negative high voltage pulse to an alumina carrier layer. A high voltage pulse value used in the test was −60 kV and 40 μsec, and a frequency was synchronized with the magnetron deposition source to the same frequency of 100 Hz. In addition, after a pulse direct current for the magnetron deposition source was applied for 200 μsec, high voltage pulse was applied to the alumina carrier layer for 40 μsec after approximately 100 μsec, and thereby plasma ion implantation was performed at a sufficiently high ion density of plasma.

### COMPARATIVE EXAMPLE

For the same porous alumina carrier layer as in Example, Pt particles were carried using impregnation. To this end, a 0.50 wt % Pt particle solution was prepared by dissolving potassium hexachloroplatinate (4; K₂PtCl₆) in distilled water. The porous alumina carrier layer was dipped in the solution, taken therefrom and heated at 500° C. for 3 hours to remove moisture.

### Evaluation of Catalyst Characteristic

[Comparison in Size of Catalyst Particle Carried in Carrier]

To examine dispersion and particle size of Pt particles present on surfaces of the catalysts fabricated in Example and Comparative Example, cross-sections of respective catalysts were observed by TEM.

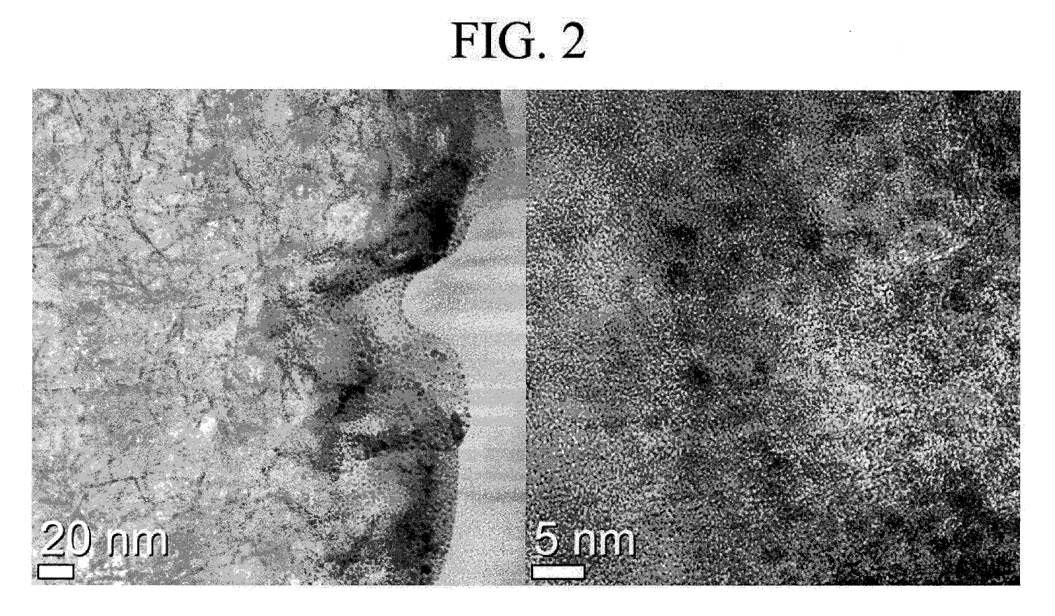

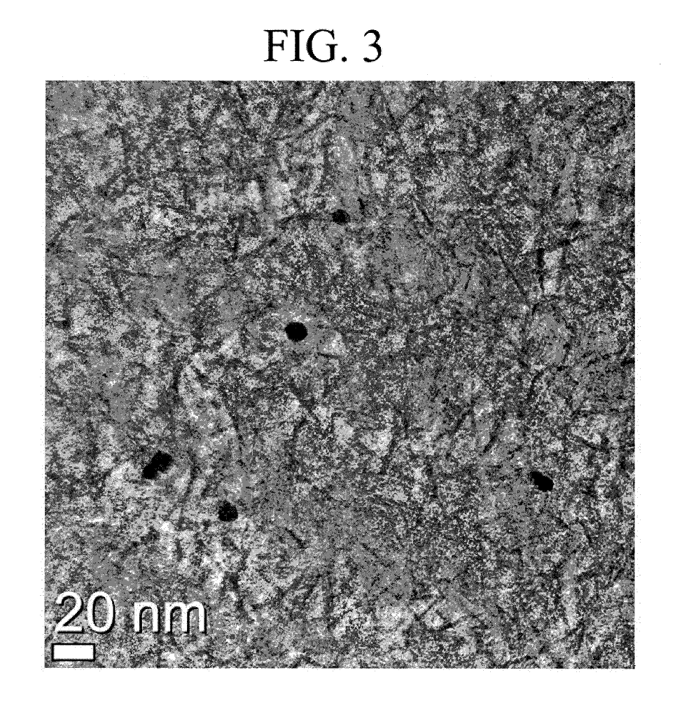

FIG. 2 shows the catalyst fabricated in Example, and FIG. 3 shows the catalyst fabricated in Comparative Example.

In the left image of FIG. 2, an ion-implanted Pt layer was observed to have a thickness of approximately 50 to 100 nm, and in the right enlarged image, the dark, round objects are Pt particles, each of which has a size of approximately 2 to 3 nm. On the other hand, in FIG. 3, the black spots are Pt particles, each of which has a size of several to several tens of nanometers. That is, it is noted that a smaller solid element particle can be carried in a carrier by the method of the present invention, compared to the impregnation.

[Evaluation of Catalytic Performance]

To evaluate the performance of the catalysts fabricated in Example and Comparative Example, a hydrogen gas generating reaction through DME reforming was performed. The [Pt/γ-alumina/Al plate] formed on one side of the Al plate having a length of 4 cm and a width of 2 cm as described above, was used as a catalyst activating plate. A reforming device was configured such that two activating plates were disposed to face each other and DME gas flowed between the plates. Here, a fuel (gas state) was provided at 5 ml/min and a space velocity (GHSV) of 2000 h⁻¹. DME, O₂ and N₂ gases were provided in a ratio of 5 cc:6 cc:20 cc.

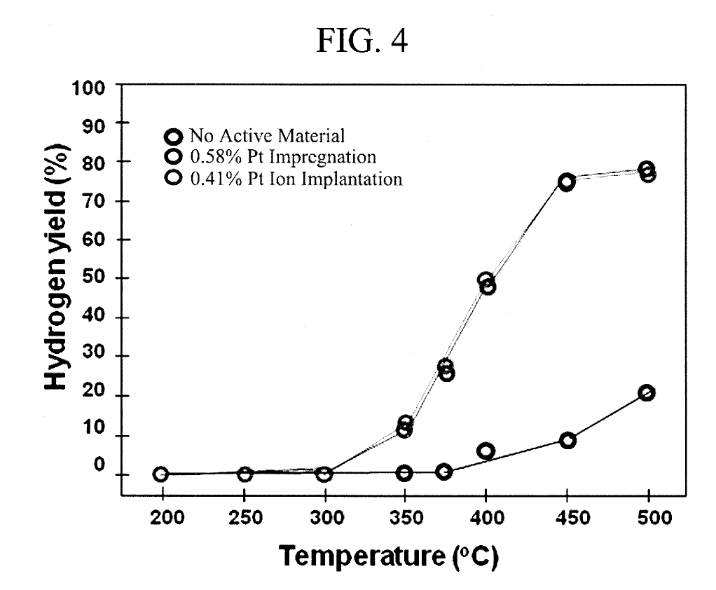

The DME was partially oxidation reformed at a temperature of 200 to 500° C., and the result is shown in FIG. 4. As shown in FIG. 4, it was shown that hydrogen yields generated according to a temperature were almost similar in both catalysts.

After the performance evaluation, an amount of Pt actually contained in each catalyst was evaluated by impregnated carbon procedure (ICP) analysis. As a result, the catalyst fabricated in Example was contained at 0.41 wt %, and the catalyst fabricated in Comparative Example was contained at 0.58 wt %. That is, in the case of the catalysts of Example and Comparative Example showing the same catalytic performance, it is actually shown that the catalyst fabricated by plasma ion implantation according to the present invention contained catalyst components in an amount approximately 30% less than that fabricated by impregnation.

Therefore, it can be noted that when the method of the present invention is used to realize the same catalytic performance, an amount of the used catalyst components can be reduced, compared to the conventional impregnation.

According to the present invention, a small amount of solid element catalyst components can be effectively carried in a porous carrier.

In addition, the use of a catalyst fabricated in the present invention does not cause agglomeration of particles of the catalyst components carried in the carrier or release of the catalyst component from the carrier, even when exposed to high temperature and humidity environments for a long time. Thus, performance of the catalyst can be maintained and a lifespan of the catalyst can be prolonged.

Furthermore, in the catalyst fabricated in the present invention, the particle of the catalyst component is small and thus a surface area of a catalyst active component can be increased.

The present invention has been shown and described with reference to certain exemplary embodiments thereof, it will be understood by those skilled in the art that various changes in form and details may be made therein without departing from the scope of the invention as defined by the appended claims.

What is claimed is:

1. A method of fabricating a nano particle complex catalyst, comprising:
generating a plasma ion of a solid element used as a catalyst component in a vacuum container which is maintained in a vacuum state; and
accelerating and implanting the ionized catalyst component from the generated plasma ion into a surface of a porous carrier.

2. The method according to claim 1, wherein the solid element plasma ion is generated by supplying pulse direct current power which is maintained at low average power but has a high power level at the moment a pulse is applied to a deposition source.

3. The method according to claim 2, wherein the pulse direct current power has a density of 10 W/cm² to 10 kW/cm², a frequency of 1 Hz to 10 kHz and a pulse width of 10 μsec to 1 msec.

4. The method according to claim 2, wherein a high voltage pulse synchronized with the pulse direct current power is applied to the porous carrier to accelerate the solid element plasma ion toward the porous carrier.

5. The method according to claim 4, wherein the high voltage pulse has a frequency of 1 Hz to 10 kHz, a pulse width of 1 to 200 μsec and a negative-pulse high voltage of −1 to −100 kV.

6. The method according to claim 1, wherein a plasma generating gas is injected into the vacuum container at a pressure of 0.5 to 5 mTorr.

7. The method according to claim 1, wherein the porous carrier is at least one selected from the group consisting of Si—O, Sn—O, Al—O, Cr—O, Mo—O, Ti—O, Zr—O, Mg—O, W—O, V—O, Sb—O, and RE (rare earth elements: Sr, Y, lanthanum group)-O-based oxides.

8. The method according to claim 1, wherein the solid element is at least one selected from the group consisting of Au, Ag, Cu, Co, Ni, Pt, Pd, Ru, Ir and Rh.

9. The method according to claim 1, wherein plasma is further introduced into the vacuum container.

10. The method according to claim 1, wherein the porous carrier includes a carrier layer having a thickness of 1 to 100 μm formed on a metal or ceramic substrate.

11. A device for fabricating a nano particle complex catalyst, comprising:
a vacuum container maintained in a vacuum state;
a deposition source for emitting an ion of a solid element into the vacuum container by pulse direct current power which is maintained at a low average power and has a high power level at the moment a pulse is applied; and
a porous carrier disposed in the vacuum container to face the deposition source and implanting the ion of the solid element by a high voltage pulse synchronized with the pulse direct current power.

12. The device according to claim 11, wherein a plasma generating gas is injected into the vacuum container to form the ion of the solid element in a plasma state.

13. The device according to claim 12, wherein plasma is further introduced into the vacuum container.
